(19) United States
(12) Patent Application Publication
(10) Pub. No.: US 2026/0196850 A1
(43) Pub. Date: Jul. 9, 2026

(54) POWER STORAGE SYSTEM

(71) Applicant: FUJI ELECTRIC CO., LTD., Kanagawa (JP)

(72) Inventors: Ryuji YAMADA, Hachioji-city (JP); Kazuyuki YODA, Kobe-city (JP)

(21) Appl. No.: 19/560,132

(22) Filed: Mar. 9, 2026

Related U.S. Application Data
(63) Continuation of application No. PCT/JP2025/002613, filed on Jan. 28, 2025.

(30) Foreign Application Priority Data
Mar. 6, 2024 (JP) 2024-034186

(51) Int. Cl. H02J 7/34; G01R 31/3835; G01R 31/392; H01M 10/42; H01M 10/48; H01M 50/512; H02J 7/90; H02M 3/158

(52) U.S. Cl. CPC H02J 7/342; G01R 31/3835; G01R 31/392; H01M 10/425; H01M 10/482; H01M 50/512; H02J 7/933; H02M 3/158; H02J 2207/20

(57) ABSTRACT

There is provided a power storage system including: a DC bus; a plurality of batteries which are connected to the DC bus, and which are connected to each other in parallel; a plurality of diagnosis units each of which is provided for each of the plurality of batteries and measures a degradation state of a battery that is included in the plurality of batteries, by causing the battery to be discharged at a constant current or constant power; and a power conditioner which is connected to the DC bus, and which performs conversion between DC power and AC power, in which at least a part of power discharged from a battery under test among the plurality of batteries, the degradation state of which is being measured by the diagnosis unit, is charged into another at least one battery among the plurality of batteries, or is supplied to the power conditioner.

The contents of the following patent application(s) are incorporated herein by reference:
NO. 2024-034186 filed in JP on Mar. 6, 2024
NO. PCT/JP2025/002613 filed in WO on Jan. 28, 2025.

### BACKGROUND

### 1. Technical Field

The present invention relates to a power storage system.

### 2. Related Art

In the related art, a power system in which battery parts each consisting of a secondary battery are connected, respectively, with power conversion circuits in parallel, is known (refer to Patent Document 1).

### RELATED ART DOCUMENTS

### Patent Document

Patent Document 1: Japanese Patent Application Publication No. 2013-135482

### BRIEF DESCRIPTION OF THE DRAWINGS

FIG. 1 is a diagram showing an example of a power storage system 100 in an embodiment of the present invention.

FIG. 2 is a diagram showing an operation example of the power storage system 100 in an embodiment of the present invention.

FIG. 3 is a diagram showing a communication network of the power storage system 100 in an embodiment of the present invention.

FIG. 4 is a diagram showing a modification example of the power storage system 100 in an embodiment of the present invention.

### DESCRIPTION OF EXEMPLARY EMBODIMENTS

The present invention will be described below through embodiments of the invention, but the following embodiments do not limit the invention according to the claims. Further, not all of combinations of features described in the embodiments are essential to the solving means of the invention. In addition, in the case where the same configuration is shown in each drawing, description thereof may be omitted by providing the same reference numerals.

In the present specification, phrases such as “connected” are not limited to being directly connected without another element but shall include being indirectly connected via another element. In addition, in the present specification, phrases such as “connected between . . . and . . . ”, “provided between . . . and . . . ”, or “arranged between . . . and . . . ” shall mean “electrically connected to . . . and . . . ” rather than limiting physical arrangement.

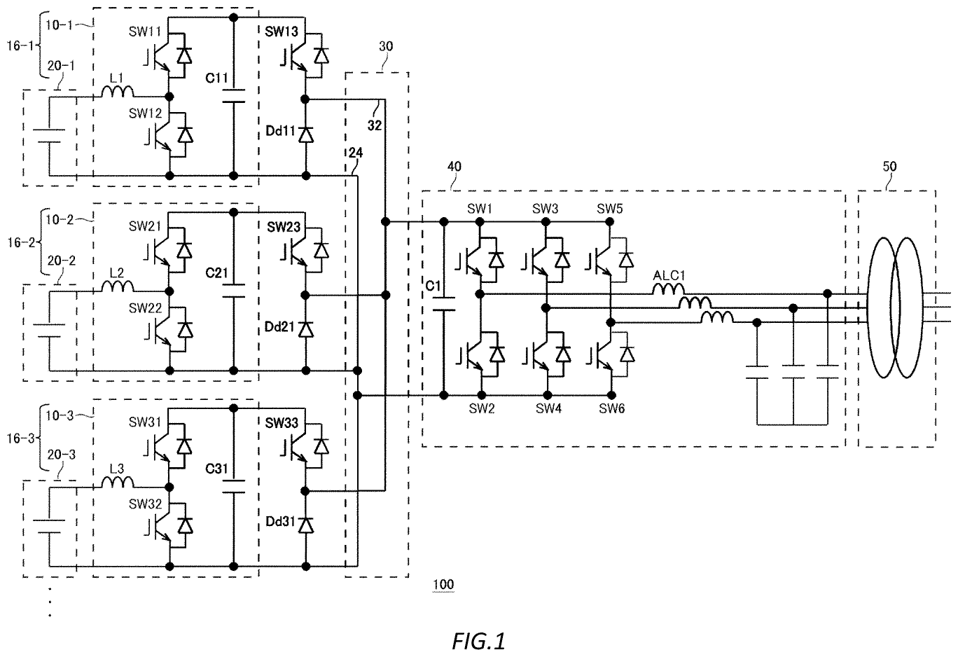

FIG. 1 is a diagram showing an example of a power storage system 100 in an embodiment of the present invention. The power storage system 100 is connected to a power facility, stores power from the power facility, and also supplies power to the power facility. The power facility includes, for example, a power generation facility using renewable energy. The power storage system 100 stores surplus power from the power generation facility, and also supplies power from the power storage system 100 when there is a shortage of power in the power generation facility. The power facility may be an electrical grid. The power storage system 100 supplies power for the electrical grid, and also stores power from the electrical grid.

The power storage system 100 includes a plurality of power storage units 16, a DC bus 30, a power conditioner 40, and a transformer 50. Each of the power storage units 16 is configured with a DC-DC converter 10 and a battery 20, and is connected to the DC bus 30. The DC-DC converter 10 is provided between each of a plurality of batteries 20 and the DC bus 30. The plurality of batteries 20 are connected to the DC bus 30 via the DC-DC converters 10 which are respectively connected to the plurality of batteries 20, and are connected to each other in parallel. The battery 20 may be a secondary battery such as a lithium ion battery. The battery 20 is, for example, a lithium ion battery that has been used as a battery for an EV. In general, the lithium ion battery is not easy to recycle, and thus is preferably reused as much as possible. By using a used secondary battery as the battery 20, it is possible to reuse the secondary battery. At least one battery 20 may be the used battery. The batteries 20 respectively output predetermined battery voltages different from each other.

The DC-DC converter 10 converts a battery voltage to a voltage of the DC bus 30 (for example, stepping up the voltage). The battery voltage is a voltage at an output terminal of the battery 20. The DC-DC converter 10 may convert the voltage of the DC bus 30 into the battery voltage (for example, stepping down the voltage) and charge the battery 20.

A DC-DC converter 10-1 of the present example has a switch SW11, a switch SW12, an inductor L1, and a capacitor C11. The DC-DC converter 10-1 of the present example converts the voltage by operating as a step-up chopper or a step-down chopper. Note that the configuration of the DC-DC converter 10-1 is not limited to this. The DC-DC converter 10-1 only needs to be able to convert the voltage.

The plurality of DC-DC converters 10 are connected to the DC bus 30. In FIG. 1, three DC-DC converters 10 and three batteries 20 are shown; however, the power storage system 100 may include more DC-DC converters 10 and more batteries 20.

DC power is applied to the DC bus 30. In the present example, the plurality of batteries 20 are connected to the DC bus 30. Each of the DC-DC converters 10 may be operated such that the voltage of the DC bus 30 maintains a predetermined value. The DC bus 30 of the present example includes a high potential line 32 and a reference potential line 24. The high potential line 32 has a voltage higher than that of the reference potential line 24. The reference potential line 24 is connected to a low potential side terminal of each of the batteries 20. The high potential line 32 is connected to an output terminal of each of the DC-DC converters 10. The voltage of the DC bus 30 is a potential difference between the high potential line 32 and the reference potential line 24.

The power conditioner 40 performs a conversion of DC power and AC power. One side of the power conditioner 40 is connected to the DC bus 30, and another side is connected to the transformer 50. The power conditioner 40 converts the DC power of the DC bus 30 into the AC power and supplies the AC power to the transformer 50. In addition, the power conditioner 40 converts the AC power of the transformer 50 into the DC power and supplies the DC power to the DC bus 30.

The power conditioner 40 of the present example has a capacitor C1 which is charged by the voltage of the DC bus 30 or the voltage from the transformer 50. The power conditioner 40 of the present example includes a three-phase inverter which converts the DC power from the capacitor C1 into the AC power, and which converts the AC power from the transformer 50 into the DC power. The three-phase inverter has switches SW1 to SW6; and the switches SW1 and SW2, the switches SW3 and SW4, and the switches SW5 and SW6 correspond to each arm of the three-phase inverter. An inductor ALC1 is connected to a connection point of the switches in each arm. A capacitor may be provided between each inductor ALC1 and a reference potential. Note that the structure of the power conditioner 40 is not limited to this. The power conditioner 40 only needs to be able to convert the DC power and the AC power into each other.

The transformer 50 converts the voltage of the AC power. The transformer 50 converts the voltage of the AC power that is output from the power conditioner 40, and outputs the converted voltage to the power facility. In addition, the transformer 50 converts the voltage of the AC power of the power facility, and outputs the converted voltage to the power conditioner 40.

It should be noted that the power conversion of power by the power conditioner 40 is not limited to the conversion between the DC power and the AC power, and it is only needed to be able to convert power to be transmitted and received by the power storage system 100, to power which is suitable for the transmission and the reception. That is, FIG. 1 describes a circuit configuration in which the DC power and the AC power are converted into each other by the power conditioner 40 and the transformer 50; however, the present invention is not limited to this circuit configuration, and a circuit configuration which converts the DC power to the DC power may be used.

A limiting switch SW13 may be provided between the DC-DC converter 10 and the DC bus 30. Further, a freewheeling diode Dd11 may be provided between the limiting switch SW13 and the reference potential line 24. The limiting switch SW13 limits a current flowing to the DC bus 30. The limiting switch SW13 may be a semiconductor switch. The freewheeling diode Dd11 ensures a current path of the current flowing during an off period of the limiting switch SW13. The limiting switch SW13 and the freewheeling diode Dd11 may be provided for each of the DC-DC converters 10.

As described above, the battery 20 includes a used secondary battery. Each of the batteries 20 may differ in type, usage history, or the like of the battery. In general, the battery degrades by repeating charging and discharging, or by performing charging and discharging under extreme conditions. Due to degradation, characteristics such as capacity and an output voltage of the battery deteriorate, and charging and discharging characteristics at a high current value deteriorates. Specifically, when a C-rate is increased during the charging and discharging, the capacity and the output voltage of the battery are sharply decreased. Therefore, when the secondary battery is reused, it is preferable to set an appropriate C-rate for each of the batteries 20 according to a degradation state. For this purpose, it is preferable to measure the degradation state of each of the batteries 20 with high precision, and accurately grasp the degradation state of each of the batteries 20.

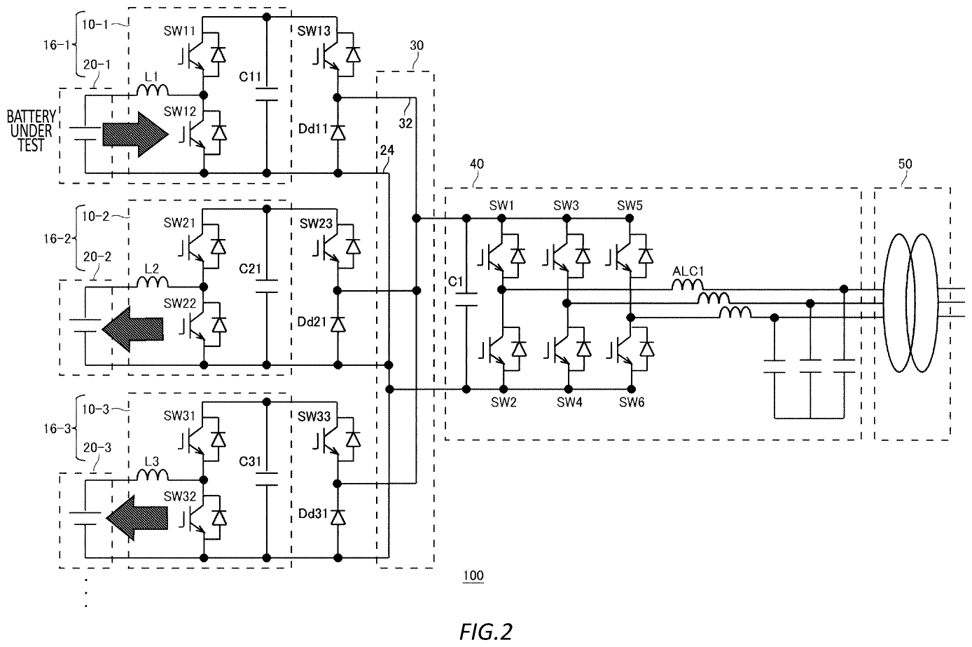

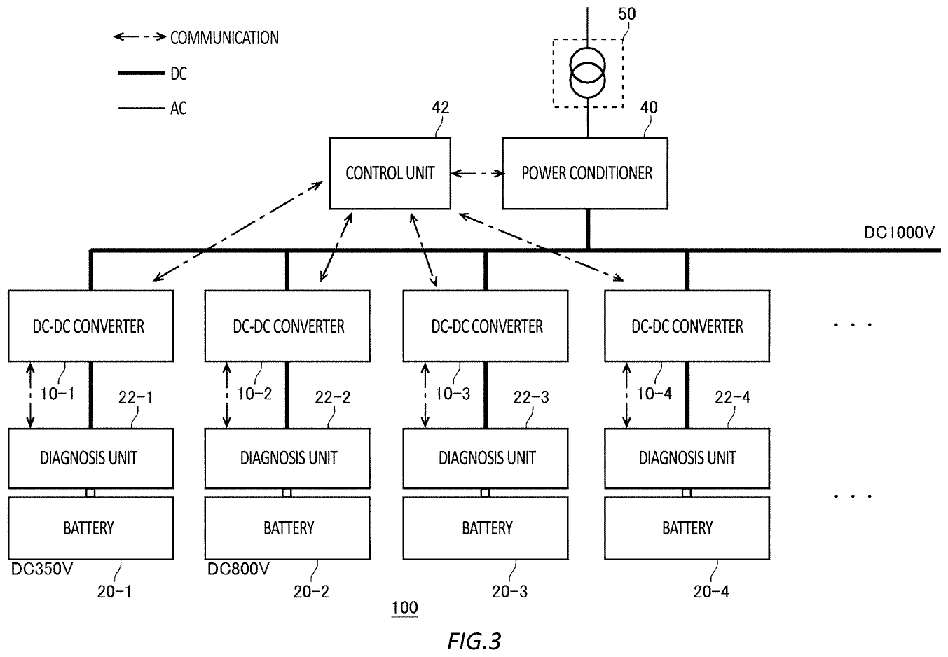

FIG. 2 is a diagram showing an operation example of the power storage system 100 in an embodiment of the present invention. A diagnosis unit shown in FIG. 3 is provided for each of the plurality of batteries 20. The diagnosis unit may be a battery management system which measures a current, a voltage, a temperature, or the like of the battery. The battery management system may be reused after being used for another application (for example, for the EV).

The diagnosis unit may measure the degradation state of the battery 20 by causing the battery 20 to be discharged at a constant current or constant power. The diagnosis unit may measure the electrical characteristics such as discharge capacity (Ah), an output voltage (V), an output current (A), output power (W), output energy (Wh), and internal impedance (Q) of the battery 20. The discharge capacity is an amount of electricity in a case of the discharge from a fully charged state until the output voltage is decreased to a predetermined value. When the discharge capacity is measured, it is preferable to charge the battery 20 in advance. The diagnosis unit may acquire a time waveform by measuring the electrical characteristics such as the output voltage at a plurality of timings. The diagnosis unit may measure a rate of change of the electrical characteristics such as the output voltage, with respect to a discharge time.

The diagnosis unit may calculate, as the degradation state, a degree of degradation from a predetermined initial state, for at least a part of these electrical characteristics. For an initial state of each characteristic, a specification value of the battery 20 may be used, or a characteristic value first measured by the diagnosis unit for the battery 20 may be used.

More specifically, the degradation state is, for example, a degree of decrease in capacity or output voltage at a high rate, in the charging and discharging characteristics (rate characteristics) of the battery. The measuring of the degradation state may be estimating the degradation state or calculating the rate characteristics from an amount of voltage drop of the battery when discharged at a constant current or constant power, or may be directly measuring the rate characteristics. As another measurement method, it is also possible to determine the degradation state by estimating an electromotive force and an internal resistance during the charging or discharging from a relationship between the battery voltage and the current during normal operation. In addition, it is possible to estimate the degradation state from the usage history of the battery. However, the degradation state that is estimated by these methods is not so accurate. On the other hand, as in the present example, by measuring the amount of voltage drop of the battery when discharged at a constant current or constant power for discharge measurement, it is possible to accurately measure the degradation state of the battery 20. As an example, the diagnosis unit measures the degradation state by causing the battery 20 to be discharged at a constant current or power for about 5 seconds to 10 seconds.

The diagnosis unit may update the degradation state based on the amount of voltage drop of the battery, and a past measurement result of the amount of voltage drop of the battery. The past measurement result is, for example, an average value of the measurement results of the battery voltage obtained for a predetermined number of times in the past. This makes it possible to suppress influences of measurement errors and temporary fluctuations in the degradation state of the battery, and makes it possible to perform a more accurate measurement. The diagnosis unit may update the degradation state based on the past measurement result of the amount of voltage drop of the battery.

In addition, the diagnosis unit may update the degradation state based on both of the amount of voltage drop of the battery, and the past measurement result of the amount of voltage drop of the battery. For example, a remaining useful life of the battery may be estimated as the degradation state, from a relative change in the degradation state. This makes it possible to predict a replacement timing of the battery.

In the present specification, the battery 20 among the plurality of batteries 20, the degradation state of which is being measured by the diagnosis unit, may be referred to as a battery under test. In the example of FIG. 2, a battery 20-1 is the battery under test. The battery under test is discharging power. The arrow extending rightward from the battery 20-1 in the figure indicates the discharge. In addition, for example, when the measurement of the degradation state of the battery 20-1 ends and subsequently the diagnosis unit is measuring the degradation state of a battery 20-2, the battery 20-2 becomes the battery under test.

At least a part of the power discharged from the battery under test is charged into another at least one battery 20 among the plurality of batteries 20, or is supplied to the power conditioner 40. When the power discharged from the battery under test is supplied to the DC bus 30, it may be deemed that at least a part of the power discharged from the battery under test is charged into another at least one battery 20 among the plurality of batteries 20, or is supplied to the power conditioner 40. This makes it possible to effectively utilize the power discharged during the measurement of the degradation state. All of the power discharged from the battery under test may be charged into another at least one battery 20 among the plurality of batteries 20, or be supplied to the power conditioner 40.

At least a part of the power discharged from the battery under test may be charged into another at least one battery 20 among the plurality of batteries 20. In a case of the present example, the power discharged from the battery under test is charged into the battery 20-2 and a battery 20-3. The arrows extending leftward toward the battery 20-2 and the battery 20-3 in the figure indicate the charge. During the measurement of the degradation state, a part or all of the power discharged from the battery under test is charged into another battery 20. The period during the measurement of the degradation state may refer to a period during which the diagnosis unit is measuring the above-described electrical characteristics of the battery under test. In another example, the period during the measurement of the degradation state may refer to a period during which the battery under test is discharged at a constant current or constant power that does not depend on demanded power or surplus power of a load (the demanded power and the surplus power are referred to as load power). For each of the batteries 20, an amount of charging and discharging power is controlled according to the load power. The power storage system 100 may have a control unit which controls the amount of charging and discharging power of each of the batteries 20 according to the load power. During the period of the measurement of the degradation state of the battery under test, the control unit may control the amount of charging and discharging power of the battery 20 other than the battery under test, according to the load power. During the period of the measurement of the degradation state of the battery under test, the control unit causes the battery under test to be discharged at a constant current or constant power, regardless of the load power. The discharge current or the discharge power of the battery under test has a constant value, and thus during the period of the measurement of the degradation state of the battery under test, a surplus or shortage of the power or the current relative to the load power occurs, and the voltage of the DC bus 30 fluctuates. By controlling the charging and discharging of the battery 20 other than the battery under test to suppress the voltage fluctuation of the DC bus 30, it is possible to measure the degradation state of the battery under test without disconnecting the battery under test from the DC bus 30.

In a case where any of the batteries 20 is charged during a period in which the battery under test is discharged, it may be deemed that at least a part of the power discharged from the battery under test is charged into the battery 20. In another example, in a case where an amount of charging power of any of the batteries 20 is controlled by the control unit so as to be increased according to an amount of discharging power of the battery under test, it may be deemed that at least a part of the power discharged from the battery under test is charged into the battery 20. In addition, in a case where an amount of discharging power of any of the batteries 20 is controlled by the control unit so as to be decreased according to the amount of discharging power of the battery under test, it may be deemed that at least a part of the power discharged from the battery under test is charged into the battery 20.

In the example described above, the power discharged from the battery under test is charged into the battery 20-2 and the battery 20-3; however, a part of the power discharged from the battery under test may be charged into a capacitor C1 of the power conditioner 40. As will be described below, each of the batteries 20 is operated such that the voltage of the DC bus 30 becomes a predetermined value. Therefore, in a case where the power storage system 100 is supplying power to the power facility, each of the batteries 20 is discharging the power to the DC bus 30. At this time, the power discharged from the battery under test is charged into the capacitor C1 of the power conditioner 40. Even in this case, in another time period, the power discharged from the battery under test may be charged into another battery 20.

The plurality of DC-DC converters 10 may control the amount of charging and discharging power of the plurality of batteries 20 based on the measurement results of the degradation state by the diagnosis unit. Controlling the amount of charging and discharging power may be controlling the C-rate during the charging and discharging. As an example, as the degradation state progresses, the c-rate during the charging and discharging is decreased. The diagnosis unit may set a maximum value of an allowable C-rate from the measurement result of the degradation state. While the plurality of DC-DC converters 10 control the amount of charging and discharging power, the DC bus 30 supplies power to the load or receives power from the load. That is, during the normal power supply or power storage operation of the power storage system 100, the plurality of DC-DC converters 10 may control the amount of charging and discharging power of the plurality of batteries 20 based on the measurement results of the degradation state by the diagnosis unit. The plurality of DC-DC converters 10 may be able to communicate with the diagnosis unit, as will be described below. In addition, each of the batteries 20 may be charged and discharged in a range of about 70%±10% of the capacity.

As described above, when the battery degrades, the rate characteristic deteriorates. With the present example, even the battery in which the degradation is progressing can be used as the battery 20. In addition, an appropriate amount of charging and discharging power is used, and thus it is possible to delay the progress of degradation during use in the power storage system 100. In a case of the present example, the plurality of batteries 20 are connected in parallel, and thus even when the amount of charging and discharging power of each of the batteries 20 becomes low, it is possible to ensure a predetermined amount of charging and discharging power by combining with another battery 20. In addition, the batteries 20 of the present example are batteries having various types and usage histories, and thus the battery voltages are different from each other. The plurality of DC-DC converters 10 of the present example are respectively provided for the batteries 20, and thus batteries having battery voltages different from each other can be used as the batteries 20.

In the measurement of the degradation state in the present example, the amount of discharging power at a constant current or constant power is constant regardless of the degradation state. This makes it possible to more accurately measure the degradation state.

The DC-DC converter 10 may be selected according to the performance and the degradation state of the battery 20. For example, when a battery having a large amount of charging and discharging power is used as the battery 20-1, the DC-DC converter having a large rated current is selected as the DC-DC converter 10-1. In addition, when the degradation of the battery 20-1 progresses and the amount of charging and discharging power is decreased, the DC-DC converter 10-1 may be replaced with a DC-DC converter having a smaller rated current.

FIG. 3 is a diagram showing a communication network of the power storage system 100 in an embodiment of the present invention. The present example schematically shows each configuration of the power storage system 100. FIG. 3 represents wiring to which the DC power is applied by a bold line, and represents wiring to which the AC power is applied by a thin line. The DC power is applied to a battery 20 side relative to the power conditioner 40, and the AC power is applied to a transformer 50 side relative to the power conditioner 40.

As described above, the diagnosis unit 22 is provided for each of the plurality of batteries 20. That is, the power storage system 100 includes a plurality of diagnosis units 22. The power storage system 100 may further include a control unit 42. The control unit 42 may be able to communicate with the power conditioner 40, may be able to communicate with the plurality of DC-DC converters 10, or may be able to communicate with the plurality of diagnosis units 22. In addition, the DC-DC converter 10 may be able to directly communicate with the diagnosis unit 22, or may be able to communicate with the diagnosis unit 22 via the control unit 42. The control unit 42 may indirectly acquire the measurement result of each of the diagnosis units 22 by communicating with each of the DC-DC converters 10. The control unit 42 may indirectly control the DC-DC converter 10 via the diagnosis unit 22. The arrow of the dash-single dotted line in the figure shows an example of a communication status between the respective components.

The control unit 42 controls each of the DC-DC converters 10 according to the voltage of the DC bus 30. The control unit 42 may control each of the DC-DC converters 10 such that the voltage of the DC bus 30 becomes a predetermined value. The control unit 42 may perform a droop control on each of the DC-DC converters 10 as an example.

While the diagnosis unit 22 measures the degradation state of the battery under test, the DC bus 30 may supply power to the load or receive power from the load. That is, during the normal power supply or power storage operation of the power storage system 100, the diagnosis unit 22 measures the degradation state of the battery under test. While the diagnosis unit 22 measures the degradation state of the battery under test, another at least one battery 20 among the plurality of batteries 20 may be charged or discharged according to the voltage of the DC bus 30, or all of the other batteries 20 may be charged or discharged according to the voltage of the DC bus 30.

While the diagnosis unit 22 measures the degradation state of the battery under test, the control unit 42 may charge and discharge the battery 20 by controlling at least one or all of the other DC-DC converters 10. As an example, the control unit 42 may regard the battery under test as the load, and perform the droop control on at least one or all of the other DC-DC converters 10. This makes it possible to measure the degradation state of the battery under test without stopping the operation of the power storage system 100.

The control unit 42 may calculate a total capacity of the plurality of batteries 20 from measurement results of the degradation state by the diagnosis unit 22, and control an amount of power conversion of the power conditioner 40 based on the total capacity of the plurality of batteries 20. The unit of the total capacity that is calculated may be W, or may be Wh. As an example, the control unit 42 updates an upper limit value of an amount of convertible power of the power conditioner 40 based on the calculated total capacity.

By controlling the diagnosis unit 22, the control unit 42 may adjust a number of the battery under test which is simultaneously measured, based on capacities of the plurality of batteries 20 calculated from the measurement results by the plurality of diagnosis units 22. Here, the case of being simultaneously measured may include not only a case where the start and the end of measurement completely coincide, but also a case where only a part of the measurement time overlaps. By increasing a number of the battery under test, the time required to measure the degradation states of all of the batteries 20 is reduced. On the other hand, except for the discharge during the measurement, the battery 20 under measurement does not contributes to the supply of power to the DC bus 30 or the storage of power from the DC bus 30. Therefore, as an example, when the capacity of the battery under test is smaller than a predetermined value, a number of the battery under test which is simultaneously measured may be increased by one. The control unit 42 may repeat a similar procedure until the total capacity of the batteries under test exceeds the predetermined value. The control unit 42 may adjust a number of the battery under test which is simultaneously measured, based on the capacities of the plurality of batteries 20 in accordance with the most recent measurement results by the plurality of diagnosis units 22. The capacities of the plurality of batteries 20 may be calculated from the past measurement results by the plurality of diagnosis units 22.

In a case where a battery is newly installed as the battery 20 in the power storage system 100, until the first measurement of the degradation state is performed, the diagnosis unit 22 may estimate the degradation state from the specification or the usage history of the battery. In this case, as well, it is possible to enhance the precision of the degradation state by subsequently discharging at a constant current or constant power to measure the degradation state.

In the case where a battery is newly installed as the battery 20 in the power storage system 100, the control unit 42 may estimate the capacity of the battery 20 from the specification or the usage history of the battery. The control unit 42 may adjust a number of the battery under test which is simultaneously measured, based on the estimated capacity. The control unit 42 may preferentially measure the degradation state of the newly installed battery 20.

By controlling the diagnosis unit 22, the control unit 42 may sequentially measure the degradation state of each of the batteries 20. By controlling the diagnosis unit 22, the control unit 42 may periodically measure the degradation state of each of the batteries 20. The degradation states of all of the batteries 20 may be periodically measured. As an example, the degradation state may be diagnosed every week, the degradation state may be diagnosed every month, and the degradation state may be diagnosed every year.

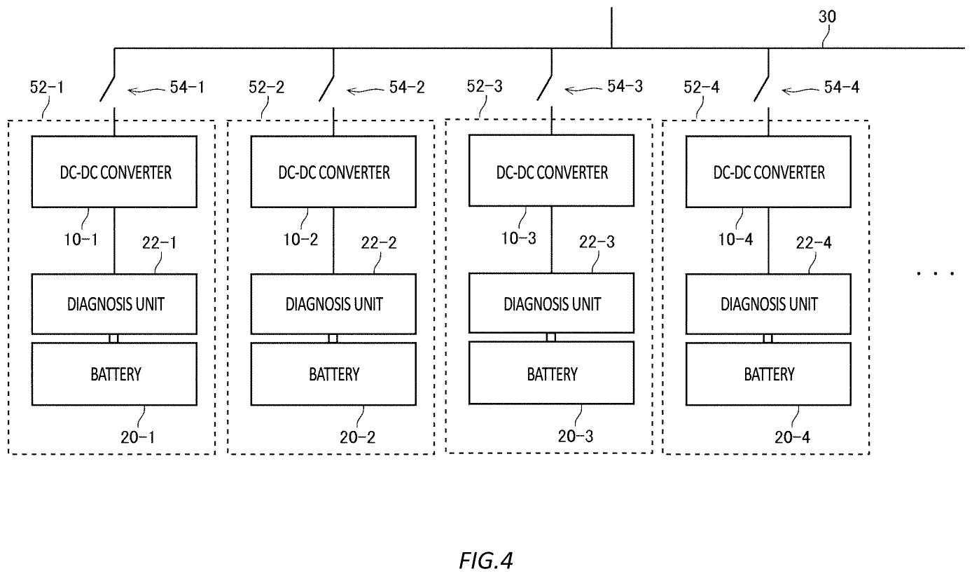

FIG. 4 is a diagram showing a modification example of the power storage system 100 in an embodiment of the present invention. FIG. 4 illustrates only the configuration from the DC bus 30 to the battery 20 of the power storage system 100.

The battery 20, the diagnosis unit 22, and the DC-DC converter 10 of the present example serve as one module 52. In FIG. 4, each of the battery 20, each of the diagnosis unit 22, and each of the DC-DC converter 10 serve as one module 52 to illustrate a total of four modules 52. The module 52 may include a housing which accommodates the battery 20, the diagnosis unit 22, and the DC-DC converter 10. The housing may be formed of an insulating material such as resin or ceramic. Each of the modules 52 may be connected to the DC bus 30 via a mechanical switch 54. The mechanical switch 54 may be provided between the DC-DC converter 10 and the DC bus 30. As an example, the mechanical switch 54 is a breaker.

The battery 20, the diagnosis unit 22, and the DC-DC converter 10 of the present example are detachably attachable to the DC bus 30 for each of the modules 52. This makes it easy to replace the battery 20. In addition, the voltage of the module 52 becomes equal to the voltage of the DC bus 30 by the DC-DC converter 10, and thus it is not necessary to match the voltages, and it is possible to easily and safely replace the battery 20.

The power storage system 100 may include a slot which detachably accommodates each of the modules 52. Each slot has a shape in accordance with an external shape of the module 52. For example, by mounting the module 52 in each slot, the module 52 is connected to the DC bus 30 via the mechanical switch 54. The plurality of slots may be aligned in a predetermined direction, or may be two-dimensionally aligned in two directions.

The control unit 42 may control the DC-DC converter 10 according to the measurement result of the degradation state by the diagnosis unit 22, and disconnect the DC-DC converter 10 from the DC bus 30. As an example, in a case where the maximum value of the allowable C-rate described above falls below a predetermined value, the control unit 42 disconnects the DC-DC converter 10 from the DC bus 30. In this manner, a battery in which the degradation progresses, and which can no longer be used as the battery 20 is disconnected from the power storage system 100.

In FIG. 4, in a case of disconnecting the DC-DC converter 10-1 from the DC bus 30, the control unit 42 first turns off the switches SW11 and SW12 of the DC-DC converter 10. In this manner, the operation of stepping up or stepping down by the DC-DC converter 10 stops. Here, when the switch SW13 is turned on, the voltage of the capacitor C11 of the DC-DC converter 10 becomes equal to that of the capacitor C1 of the power conditioner 40. After the capacitor C1 and the capacitor C11 reach the same potential, the switch SW13 is turned off. Finally, the mechanical switch 54 is turned off, and the whole module 52 is removed from the DC bus 30.

While the embodiments of the present invention have been described, the technical scope of the present invention is not limited to the above-described embodiments. It is apparent to persons skilled in the art that various alterations or improvements can be added to the above-described embodiments. It is also apparent from the described scope of the claims that the embodiments to which such alterations or improvements are added can be included in the technical scope of the present invention.

What is claimed is:

1. A power storage system comprising:
a DC bus;
a plurality of batteries which are connected to the DC bus, and which are connected to each other in parallel;
a plurality of diagnosis units each of which is provided for each of the plurality of batteries, and measures a degradation state of a battery that is included in the plurality of batteries, by causing the battery to be discharged at a constant current or constant power; and
a power conditioner which is connected to the DC bus, and which performs conversion between DC power and AC power, wherein
at least a part of power discharged from a battery under test among the plurality of batteries, the degradation state of which is being measured by a diagnosis unit which is included in the plurality of diagnosis units, is charged into another at least one battery among the plurality of batteries, or is supplied to the power conditioner.

2. The power storage system according to claim 1, wherein
at least a part of power discharged from the battery under test among the plurality of batteries is charged into the another at least one battery among the plurality of batteries.

3. The power storage system according to claim 2, wherein
while the diagnosis unit measures the degradation state of the battery under test, the DC bus supplies power to the power conditioner, or receives power from the power conditioner.

4. The power storage system according to claim 2, wherein
the diagnosis unit measures the degradation state by measuring an amount of voltage drop of the battery during a measurement of the degradation state.

5. The power storage system according to claim 4, wherein
the diagnosis unit updates the degradation state based on the amount of voltage drop of the battery, and a past measurement result of the amount of voltage drop of the battery.

6. The power storage system according to claim 2, further comprising:
a control unit which is able to communicate with the plurality of diagnosis units, wherein
the control unit adjusts a number of the battery under test which is simultaneously measured, based on capacities of the plurality of batteries calculated from measurement results by the plurality of diagnosis units.

7. The power storage system according to claim 2, further comprising:
a control unit which is able to communicate with the plurality of diagnosis units and the power conditioner; wherein
the control unit calculates a total capacity of the plurality of batteries from measurement results of the degradation state by the diagnosis unit, and controls an amount of power conversion of the power conditioner based on the total capacity of the plurality of batteries.

8. The power storage system according to claim 1, further comprising:
a plurality of DC-DC converters each of which is provided between each of the plurality of batteries and the DC bus, wherein
the plurality of DC-DC converters control an amount of charging and discharging power of the plurality of batteries based on measurement results of the degradation state by the diagnosis unit.

9. The power storage system according to claim 2, further comprising:
a plurality of DC-DC converters each of which is provided between each of the plurality of batteries and the DC bus, wherein
the battery, the diagnosis unit, and a DC-DC converter that is included in the plurality of DC-DC converters serve as one module, and the module as a whole is detachably attachable to the DC bus.

10. The power storage system according to claim 9, further comprising:
a control unit which is able to communicate with the plurality of DC-DC converters, wherein
the control unit controls the DC-DC converter according to a measurement result of the degradation state by the diagnosis unit, and disconnects the DC-DC converter from the DC bus.

11. The power storage system according to claim 3, wherein
while the diagnosis unit measures the degradation state of the battery under test, the DC bus receives power from the power conditioner.

12. The power storage system according to claim 1, further comprising:
a plurality of DC-DC converters each of which is provided between each of the plurality of batteries and the DC bus, wherein
the plurality of DC-DC converters control a C-rate during charging and discharging of the plurality of batteries based on measurement results of the degradation state by the diagnosis unit.

13. The power storage system according to claim 2, further comprising:
a plurality of DC-DC converters each of which is provided between each of the plurality of batteries and the DC bus, wherein
the plurality of DC-DC converters control an amount of charging and discharging power of the plurality of batteries based on measurement results of the degradation state by the diagnosis unit.

14. The power storage system according to claim 3, further comprising:
a plurality of DC-DC converters each of which is provided between each of the plurality of batteries and the DC bus, wherein
the plurality of DC-DC converters control an amount of charging and discharging power of the plurality of batteries based on measurement results of the degradation state by the diagnosis unit.

15. The power storage system according to claim 4, further comprising:
a plurality of DC-DC converters each of which is provided between each of the plurality of batteries and the DC bus, wherein
the plurality of DC-DC converters control an amount of charging and discharging power of the plurality of batteries based on measurement results of the degradation state by the diagnosis unit.

16. The power storage system according to claim 5, further comprising:
a plurality of DC-DC converters each of which is provided between each of the plurality of batteries and the DC bus, wherein
the plurality of DC-DC converters control an amount of charging and discharging power of the plurality of batteries based on measurement results of the degradation state by the diagnosis unit.

17. The power storage system according to claim 6, further comprising:
a plurality of DC-DC converters each of which is provided between each of the plurality of batteries and the DC bus, wherein
the plurality of DC-DC converters control an amount of charging and discharging power of the plurality of batteries based on measurement results of the degradation state by the diagnosis unit.

18. The power storage system according to claim 7, further comprising:
a plurality of DC-DC converters each of which is provided between each of the plurality of batteries and the DC bus, wherein
the plurality of DC-DC converters control an amount of charging and discharging power of the plurality of batteries based on measurement results of the degradation state by the diagnosis unit.

19. The power storage system according to claim 2, further comprising:
a plurality of DC-DC converters each of which is provided between each of the plurality of batteries and the DC bus, wherein
the plurality of DC-DC converters control a C-rate during charging and discharging of the plurality of batteries based on measurement results of the degradation state by the diagnosis unit.

20. The power storage system according to claim 3, further comprising:
a plurality of DC-DC converters each of which is provided between each of the plurality of batteries and the DC bus, wherein
the plurality of DC-DC converters control a C-rate during charging and discharging of the plurality of batteries based on measurement results of the degradation state by the diagnosis unit.
